(19) United States
(12) Patent Application Publication
(10) Pub. No.: US 2022/0287393 A1
(43) Pub. Date: Sep. 15, 2022

(54) APPARATUSES AND WEARABLE GARMENTS INCLUDING ELECTRICAL SOURCES AND CIRCUIT ELEMENTS

(71) Applicant: Armington Studios Inc., Cranston, RI (US)

(72) Inventors: Jeanette NUMBERS, Providence, RI (US); Seung Hyuk NOH, Providence, RI (US); Halle Van De Hey, McKinney, TX (US); Meghna NAYAK, Providence, RI (US)

(73) Assignee: Armington Studios Inc., Cranston, RI (US)

(21) Appl. No.: 17/622,438

(22) PCT Filed: Jun. 5, 2020
(86) PCT No.: PCT/US2020/036227

§ 371 Date: Dec. 23, 2021

Related U.S. Application Data
(60) Provisional application No. 62/868,185, filed on Jun. 28, 2019.

(51) Int. Cl. A41D 13/005; H05K 1/02; H05K 1/11

(52) U.S. Cl. CPC A41D 13/0058; H05K 1/0212; H05K 1/118; H05K 2201/10037; H05K 2201/10189

(57) ABSTRACT

An apparatus including an electrical source and a circuit board. The electrical source includes an outer shell including a receptacle, a battery arranged within the outer shell, and at least one electrical connector electrically connected to the battery and extending through the outer shell. The circuit board includes at least one circuit element and a mounting post. When the mounting post of the circuit board is received within the receptacle of the outer shell, the at least one electrical connector of the electrical source is electrically coupled to the at least one circuit element of the circuit board.

### CROSS-REFERENCE TO RELATED APPLICATION

This application is a PCT application which claims priority to co-pending U.S. Provisional Patent Application No. 62/868,158, filed Jun. 28, 2019, for “Apparatuses and Wearable Garments Including Electrical Sources and Circuit Elements,” which is hereby incorporated by reference in its entirety including the drawings.

### TECHNICAL FIELD

The present specification generally relates to apparatuses and wearable garments including electrical sources and circuit elements.

### BACKGROUND

Flexible circuits and devices, such as heating pads, may be permanently secured to a power source or use embedded wires, preventing easy removal of the circuit for replacement or cleaning. Additionally, the connection between the power source and flexible circuit may not be rigid enough to be integral in a wearable garment that a user could wear throughout a normal day due to the possibly of the power source disconnecting from the flexible circuit. Even further, the power source for these flexible circuits may be large and cannot be used in applications where space is limited.

Accordingly, there is a need for improved apparatuses and wearable garments including electrical sources and circuit elements.

### SUMMARY

A first aspect A1 includes an apparatus including an electrical source and a circuit board. The electrical source includes an outer shell including a receptacle, a battery arranged within the outer shell, and at least one electrical connector electrically connected to the battery and extending through the outer shell. The circuit board includes at least one circuit element, and a mounting post. When the mounting post of the circuit board is received within the receptacle of the outer shell, the at least one electrical connector of the electrical source is electrically coupled to the at least one circuit element of the circuit board.

A second aspect A2 includes the apparatus of aspect A1, wherein the circuit board includes a support. The at least one circuit element includes an exposed lead, wherein the exposed lead is supported by the support.

A third aspect A3 includes the apparatus of aspect A1, wherein the circuit board includes a support, wherein the at least one electrical connector and the at least one circuit element are supported by the support when the mounting post is received within the receptacle of the outer shell.

A fourth aspect A4 includes the apparatus of any of aspects A1-A3, wherein the circuit board includes a flexible circuit including an inner layer and an outer layer. At least a portion of the at least one circuit element is arranged between the inner layer and outer layer.

A fifth aspect A5 includes the apparatus of any of aspects A1-A4, wherein the at least one circuit element includes an exposed lead extending outwardly between the inner layer and the outer layer.

A sixth aspect A6 includes the apparatus of any of aspects A1-A5, wherein the mounting post is configured to be arranged within the receptacle of the outer shell by a friction fit.

A seventh aspect A7 includes the apparatus of any of aspects A1-A6, wherein the at least one electrical connector includes a plurality of spring-loaded pogo pins. The at least one circuit element includes a plurality of circuit elements. Respective spring-loaded pogo pins of the plurality of spring-loaded pogo pins are electrically coupled to respective circuit elements of the plurality of circuit elements when the mounting post of the circuit board is received within the receptacle of the outer shell.

An eighth aspect A8 includes the apparatus of any of aspects A1-A7, wherein the receptacle is a partial through-bore.

A ninth aspect A9 includes the apparatus of any of aspects A1-A8, wherein the circuit board is a flexible heating circuit.

A tenth aspect A10 includes the apparatus of any of aspects A1-A9, wherein the electrical source is removably secured to the circuit board.

An eleventh aspect A11 includes a wearable garment including a pouch. An electrical source is disposed within the pouch. The electrical source includes an outer shell including a receptacle, a battery arranged within the outer shell, and at least one electrical connector electrically connected to the battery and extending through the outer shell, and a flexible heating circuit. The flexible heating circuit includes at least one heating element including at least one circuit element and a mounting post. When the mounting post of the flexible heating circuit is received within the receptacle of the outer shell, the at least one electrical connector of the electrical source is electrically coupled to the at least one circuit element of the flexible heating circuit.

A twelfth aspect A12 includes the wearable garment of aspect A11, where the flexible heating circuit includes a support. The at least one circuit element is supported by the support.

A thirteenth aspect A13 includes the wearable garment of aspect A11, wherein the flexible heating circuit includes a support. The at least one electrical connector and the at least one heating element are supported by the support when the mounting post is received within the receptacle of the outer shell.

A fourteenth aspect A14 includes the wearable garment of any of aspects A11-A13, wherein the flexible heating circuit is disposed within the pouch of the wearable garment.

A fifteenth aspect A15 includes the wearable garment of any of aspects A11-A14, wherein the flexible heating circuit includes an inner layer and an outer layer. At least a portion of the at least one heating element is arranged between the inner layer and the outer layer.

A sixteenth aspect A16 includes the wearable garment of any of aspects A11-A15, where the at least one electrical connector includes a plurality of spring-loaded pogo pins. The at least one circuit element includes a plurality of circuit elements. Respective spring-loaded pogo pins of the plurality of spring-loaded pogo pins are electrically coupled to respective circuit elements of the plurality of circuit elements when the mounting post of the flexible heating circuit is received within the receptacle of the outer shell.

A seventeenth aspect A17 includes the wearable garment of any of aspects A11-A16, wherein the receptacle is a partial through-bore.

An eighteenth aspect A18 includes a wearable garment including a pouch. An electrical source is disposed within the pouch. The electrical source includes an outer shell including a receptacle, a battery arranged within the outer shell, and at least one electrical connector electrically connected to the battery and extending through the outer shell. The receptacle is a partial through-bore. A circuit board includes at least one circuit element and a mounting post. When the mounting post of the circuit board is received within the receptacle of the outer shell, the at least one electrical connector of the electrical source is electrically coupled to the at least one circuit element of the circuit board. The electrical source is removably secured to the circuit board.

A nineteenth aspect A19 includes the wearable garment of aspect A18, wherein the at least one electrical connector includes a plurality of spring-loaded pogo pins. The at least one circuit element includes a plurality of circuit elements. Respective spring-loaded pogo pins of the plurality of spring-loaded pogo pins are electrically coupled to respective circuit elements of the plurality of circuit elements when the mounting post of the circuit board is received within the receptacle of the outer shell.

A twentieth aspect A20 includes the wearable garment of any of aspects A18-A19, wherein the receptacle is a partial through-bore.

A twenty-first aspect A21 includes an apparatus including an electrical source and a circuit board. The electrical source includes an outer shell including a mounting post, a battery arranged within the outer shell, and at least one electrical connector electrically connected to the battery and extending through the outer shell. The circuit board includes at least one circuit element and a receptacle arranged within the circuit board. When the mounting post is engaged with the receptacle, the at least one electrical connector of the electrical source is electrically coupled to the at least one circuit element of the circuit board.

A twenty-second aspect A22 includes the apparatus of aspect A21, wherein the receptacle is a partial through-bore.

A twenty-third aspect A23 includes the apparatus of any of aspects A21-A22, wherein the circuit board further comprises a support and the at least one circuit element further comprises an exposed lead, where the exposed lead is supported by the support.

A twenty-fourth aspect A24 includes an apparatus including an electrical source and a circuit board. The electrical source includes an outer shell including a receptacle, a support plate including a mounting post, the support plate rotatably connected to the outer shell, a battery arranged within the outer shell, and at least one electrical connector electrically connected to the battery and extending through the outer shell. The circuit board includes at least one circuit element and a through-bore arranged within the circuit board. The mounting post of the support plate is received within the through-bore of the circuit board and receptacle of the outer shell, and when the mounting post is engaged with the receptacle, the at least one electrical connector of the electrical source is electrically coupled to the at least one circuit element of the circuit board.

A twenty-fifth aspect A25 includes the apparatus of aspect A24, wherein the at least one circuit element further comprises an exposed lead. The exposed lead is supported by the support plate when the mounting post is engaged with the receptacle.

A twenty-sixth aspect A26 includes the apparatus of any of aspects A24-A25, wherein the mounting post engages with the receptacle via a friction fit.

These and additional features provided by the embodiments described herein will be more fully understood in view of the following detailed description, in conjunction with the drawings.

### BRIEF DESCRIPTION OF THE DRAWINGS

The embodiments set forth in the drawings are illustrative and exemplary in nature and not intended to limit the subject matter defined by the claims. The following detailed description of the illustrative embodiments can be understood when read in conjunction with the following drawings, where like structure is indicated with like reference numerals and in which:

FIG. 1 schematically depicts a heating device, according to one or more embodiments shown or described herein;

FIG. 2 schematically depicts an electrical source of the heating device of FIG. 1, according to one or more embodiments shown or described herein;

FIG. 3 schematically depicts a circuit board of the heating device of FIG. 1, according to one or more embodiments shown or described herein;

FIG. 4A schematically depicts the heating device of FIG. 1 with the electrical source disengaged from the circuit board, according to one or more embodiments shown or described herein;

FIG. 4B schematically depicts the heating device of FIG. 1 with the electrical source engaged with the circuit board, according to one or more embodiments shown or described herein;

FIG. 5 schematically depicts a heating device, according to one or more embodiments shown or described herein;

FIG. 6 schematically depicts a heating device, according to one or more embodiments shown or described herein;

FIG. 7 schematically depicts the heating device of FIG. 1 positioned within a garment, according to one or more embodiments shown or described herein;

FIG. 8 schematically depicts the heating device of FIG. 1 positioned within a garment, according to one or more embodiments shown or described herein;

FIG. 9 schematically depicts the heating device of FIG. 1 positioned within a garment, according to one or more embodiments shown or described herein; and

FIG. 10 schematically depicts the electrical circuitry of the heating device of FIG. 1, according to one or more embodiments shown or described herein.

### DETAILED DESCRIPTION

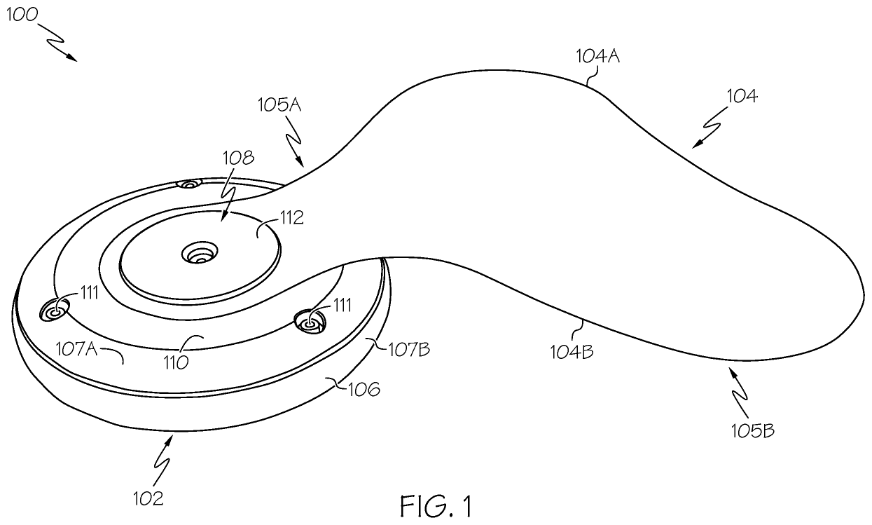

FIG. 1 generally depicts an embodiment of a heating device. The heating device generally includes an electrical source and a circuit board. The electrical source includes an outer shell including a receptacle, a battery arranged within the outer shell, and at least one electrical connector electrically connected to the battery and extending through the outer shell. The circuit board includes at least one circuit element, and a mounting post. When the mounting post of the circuit board is received within the receptacle of the outer shell, the at least one electrical connector of the electrical source is electrically coupled to the at least one circuit element of the circuit board. As will be described in greater detail herein, the electrical source may be easily and securely coupled to the circuit board. For example, the mounting post of the circuit board is held in place within the receptacle of the outer shell by a friction fit, and without the need for embedded wires. Accordingly, this connection can allow for easy removal of the circuit board from the electrical source for either replacement or cleaning of the circuit board. Additionally, the electrical source is small and has a thin profile, which can allow for use of the heating device in applications with limited space. Various embodiments of the heating device will be described in greater detail herein.

Referring now to FIG. 1, an embodiment of a heating device 100 is generally depicted. As illustrated, the heating device 100 may include an electrical source 102, a circuit board 104, and a connector assembly 108. As will be described in greater detail herein, the heating device 100 is configured to heat a specific area of a human body where the circuit board 104 is applied. It is noted that the present heating device 100 could also be used in any situation where the application of heat is required.

The electrical source 102 may include an outer shell 106. The outer shell 106 may include a top shell 107A and a bottom shell 107B. The top shell 107A may further include a flat surface 110 to allow the connector assembly 108 to sit flush against the outer shell 106. The top shell 107A and the bottom shell 107B are secured together by screws 111, but any securement means can be used without departing from the scope of the present disclosure. It is noted that the outer shell 106 and/or various components thereof may be made from a variety of materials. For example, in one non-limiting embodiment, the outer shell 106 is made from plastic (e.g., ABS).

Referring still to FIG. 1, the circuit board 104 may include an outer surface 104A, an inner surface 104B, a connector portion 105A, and a heating portion 105B. The connector portion 105A may be arranged separate from the heating portion 105B to allow the connector assembly 108 to be mounted within the circuit board 104. A support 112 of the connector assembly 108 may be securely arranged on the outer surface 104A of the circuit board 104.

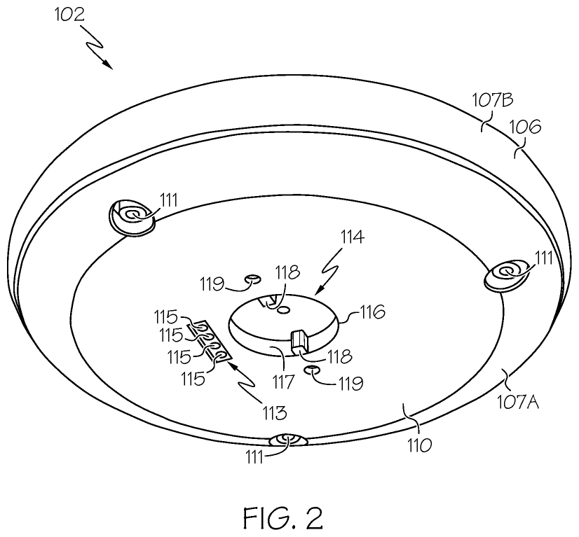

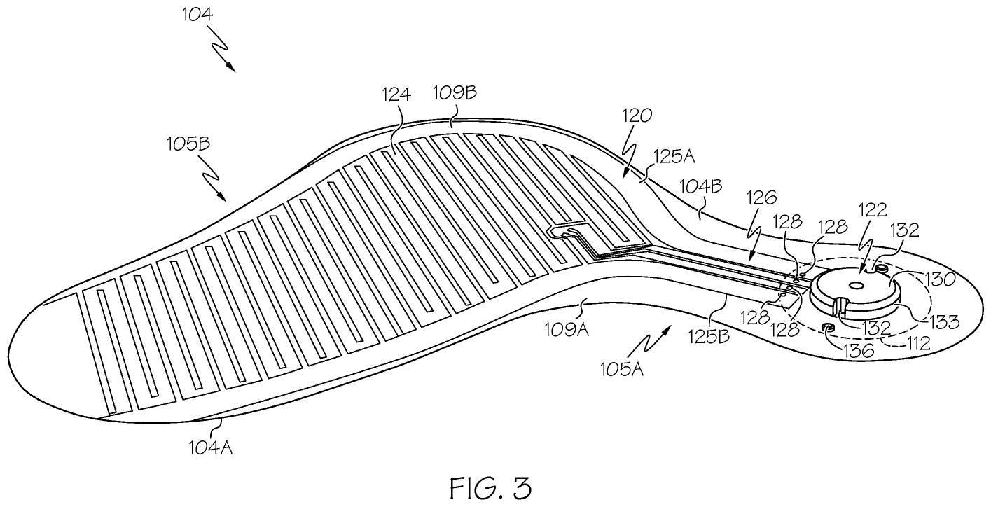

Referring now to FIG. 2, the electrical source 102 may include a circuit interface 113 and a connector interface 114. The circuit interface 113 may include electrical connectors 115. In some embodiments, the electrical connectors 115 are spring-loaded pogo pins that extend outward from the outer shell 106. The connector interface 114 includes various components that may allow the connector assembly 108 to be secured to the outer shell 106. The connector interface 114 may include a receptacle 116, ribs 118, and mounting holes 119. In some embodiments, the receptacle 116 is a partial through-bore. Ribs 118 may be arranged within receptacle 116 to prevent rotation of a mounting post 122 (See FIG. 3) of the connector assembly 108 once inserted into the receptacle 116. Additionally, the ribs 118 could increase the friction between the receptacle 116 and the mounting post 122 of the connector assembly 108 due to the increase in surface area. The receptacle 116 may include an inner surface 117 that contacts the mounting post 122 of the connector assembly 108 to create the friction fit between the electrical source 102 and the circuit board 104. Additionally, mounting holes 119 may be arranged within the flat surface 110 to receive corresponding mounting pins 136 arranged on the circuit board 104 (See FIG. 3). The mounting holes 119 may prevent rotation of the circuit board 104 once the mounting pins 136 are inserted into the mounting holes 119.

Referring now to FIG. 3, the circuit board 104 may include the connector assembly 108 and a circuit assembly 120. In some embodiments, the circuit board 104 may be assembled from multiple layers or a single layer. For example, a support layer 109A may be a durable material to provide a base for a circuit layer 109B to be arranged thereon. The support layer 109A gives the circuit layer 109B additional support. A heating circuit 124 is arranged on the circuit layer 109B prior to the circuit layer 109B being secured to the support layer 109A. However, in some embodiments, the heating circuit 124 may be directly printed on the support layer 109A. Additionally, both the support layer 109A and the circuit layer 109B may be flexible or rigid layers.

The connector assembly 108 may include the support 112, a mounting post 122, channels 132, and mounting pins 136. The mounting post 122 may be arranged on the inner surface 104B of the circuit board 104 and may be operatively arranged to be inserted into the receptacle 116 of the outer shell 106 (See FIG. 2). The mounting post 122 may include a top surface 130 and a side surface 133, which contacts the inner surface 117 of the receptacle 116 to create the friction fit between the electrical source 102 and the circuit board 104. The channels 132 may be arranged on opposite sides of the mounting post 122, and may be arranged to correspond with the ribs 118 of the receptacle 116. The mounting pins 136 are arranged on the inner surface 104B of the circuit board 104 and may be operatively arranged to correspond with the mounting holes 119 of the outer shell 106.

Still referring to FIG. 3, the circuit assembly 120 may include the heating circuit 124, a connector portion 126, and a plurality of circuit elements 128. The heating circuit 124 may be operatively arranged on the circuit layer 109B between an outer layer 125A and an inner layer 125B. In some embodiments, the circuit layer 109B is made from a polycarbonate or thermoplastic polyurethane, while the heating circuit 124 is made from an electrical conducting material, such as electrical conducting ink, and may be a positive temperature coefficient (PTC) heater. The heating circuit 124 may be arranged as to extend fully within the heating portion 105B of the circuit board 104 in various patterns, such as a zig-zag pattern.

In some embodiments, the outer layer 125A may not extend outwardly as much as the inner layer 125B along the connector portion 126, which may allow for the plurality of circuit elements 128 to extend out of the circuit layer 109B along the inner layer 125B. This arrangement of the circuit elements 128 allows for a connection to be made with the electrical connectors 115 of the electrical source 102. In some embodiments, the circuit elements 128 are exposed leads of the heating circuit 124. In some embodiments, the plurality of circuit elements 128 are arranged proximate to the connector assembly 108 since the electrical connectors 115 are arranged proximate to the receptacle 116 in a fixed orientation.

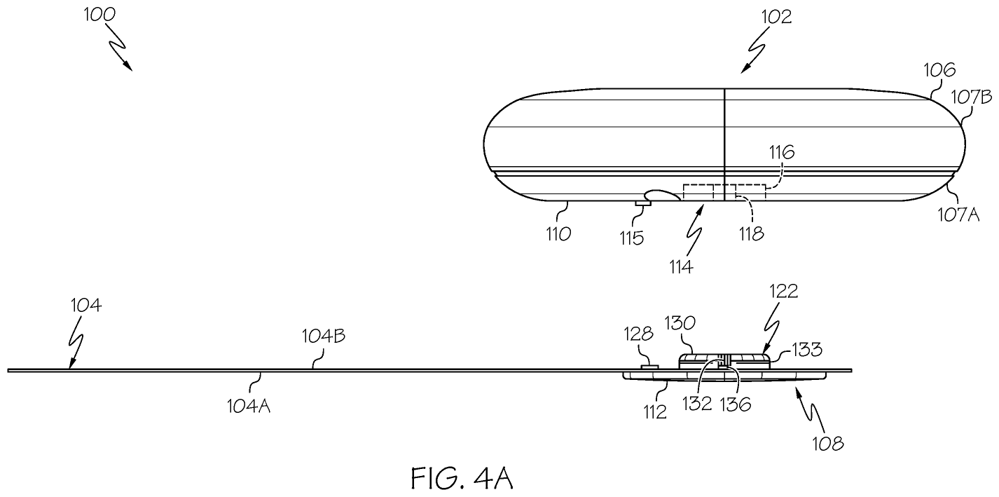

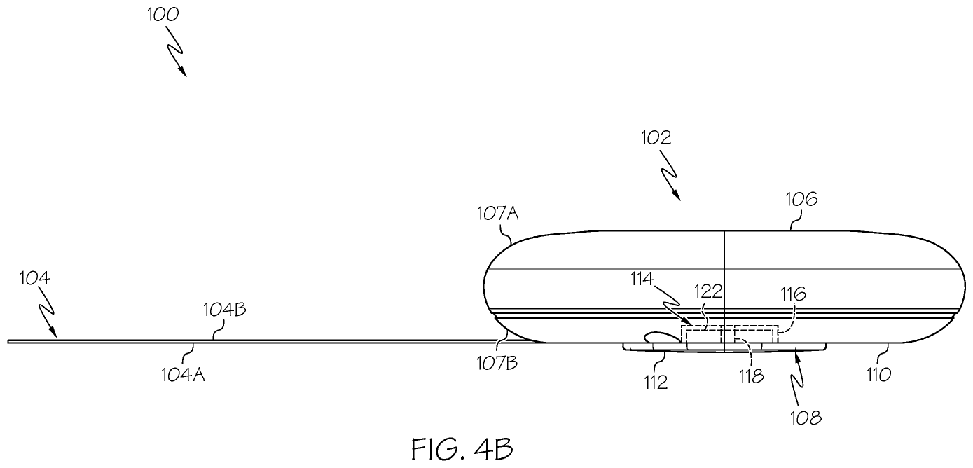

Referring now to FIGS. 4A and 4B, the electrical source 102 is removably secured to the circuit board 104 by inserting the mounting post 122 within the receptacle 116. While the mounting post 122 is inserted within receptacle 116, the electrical connectors 115 abut against the circuit elements 128 of the circuit board 104. As noted above, the electrical connectors 115 may include springs or resistance elements, which, as the electrical connectors 115 abut against the circuit elements 128, push the electrical connectors 115 into the circuit elements 128 ensuring the electrical connection between the electrical source 102 and the circuit board 104 does not become dislodged during use of the heating device 100. Additionally, as the electrical connectors 115 push against the circuit elements 128, the support 112 of the connector assembly 108 will support the circuit elements 128 from deforming or becoming dislodged. In other words, the circuit elements 128 will be sandwiched between the electrical connectors 115 pushing down on the circuit elements 128 and the support 112. In some embodiments, the support 112 may be fixedly secured to the mounting post 122. In some embodiments, the support 112 may be an integrally formed, monolithic structure with the mounting post 122.

Referring now to FIGS. 3-4B, once the mounting post 122 is removably arranged within the receptacle 116 and the electrical connectors 115 are communicatively engaged with the circuit elements 128, current is permitted to flow from the electrical source 102 to the circuit board 104. As current flows from the electrical source 102 through the heating circuit 124, heat may be generated within heating circuit 124. This generated heat may then be transferred to a user wearing the heating device 100 for the purposes of comfort directed towards a target region on the user.

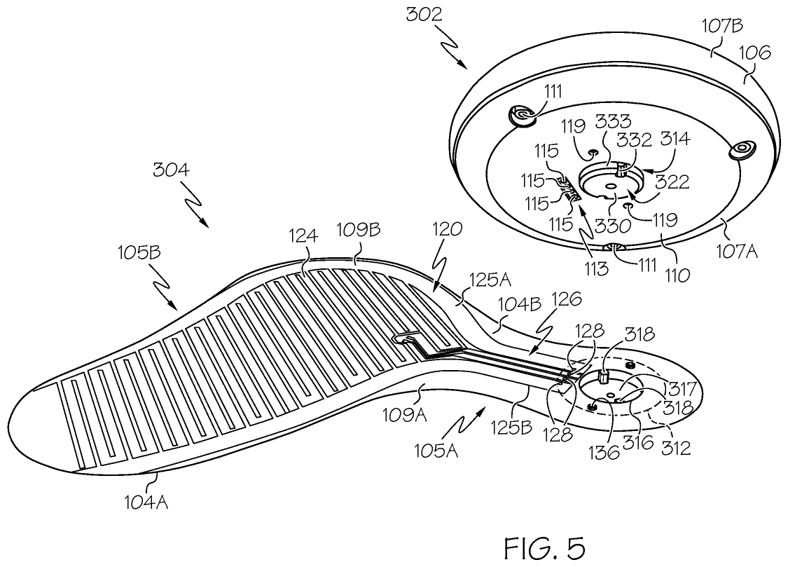

Referring now to FIG. 5, one or more embodiments may include an electrical source 302 and a circuit board 304. The electrical source 302 may include a mounting post 322 and channels 332. The mounting post 322 may be arranged on the flat surface 110 of the electrical source 302, and may be operatively arranged to be inserted into a receptacle 316 of the circuit board 304. The mounting post 322 may include a top surface 330 and a side surface 333, which contacts the inner surface 317 of the receptacle 316 to create the friction fit between the electrical source 302 and the circuit board 304. Channels 332 may be arranged on opposite sides of the mounting post 322 and may be arranged to correspond with the ribs 318 of the receptacle 316. The mounting pins 136 are arranged on the inner surface 104B of the circuit board 104 and may be operatively arranged to correspond with the mounting holes 119 of the outer shell 106.

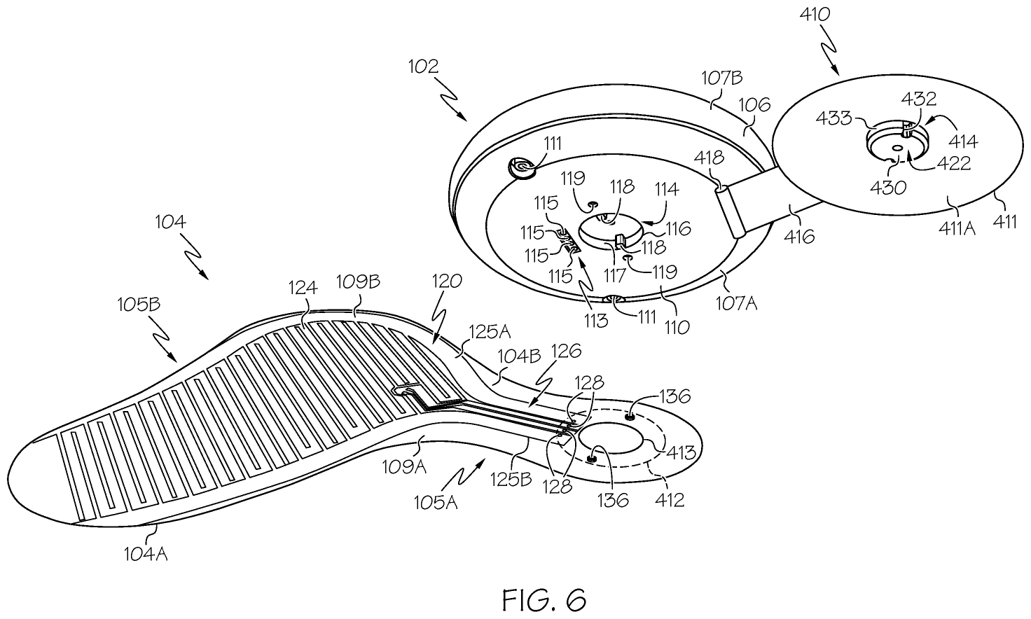

Referring now to FIG. 6, one or more embodiments may include an electrical source 402 and a circuit board 404. The electrical source 402 may include a support plate 410 having a mounting post 422 arranged on the support plate 410. The mounting post 422 may be arranged on a flat surface 411A of the support plate 410, and may be operatively arranged to be inserted into the receptacle 116 of the electrical source 402. The mounting post 422 may include a top surface 430 and a side surface 433, which contacts the inner surface 117 of the receptacle 116 to create the friction fit that encapsulates the circuit board 404 between the outer shell 106 and the support plate 410. The support plate 410 is rotatably connected to the electrical source 404 via an arm 416 and a hinge 418. The hinge 418 allows for the support plate 410 to fold over to abut the flat surface 411A of the support plate 410 against the outer surface 104A of the circuit board 404. The mounting post 422 passes through a through-bore 413 and engages with the receptacle 116 of the electrical source 402. Channels 432 may be arranged on opposite sides of the mounting post 422 and may be arranged to correspond with the ribs 118 of the receptacle 116. The mounting pins 136 are arranged on the inner surface 104B of the circuit board 104 and may be operatively arranged to correspond with the mounting holes 119 of the outer shell 106. The circuit board 404 includes a support 412 having the through-bore 413 formed therein. The support 412 is designed to provide support for the connection between the electrical connectors 115 and the plurality of circuit elements 128.

It should be noted that even though the embodiments disclosed herein use a friction fit to secure an electrical source and circuit board together, and type of any securement means can be used without departing from the scope of the present disclosure. For example, in one non-limiting embodiment the electrical source can be secured to the circuit board using screw threads arranged on the outer surface of the mounting post and on the inner surface within the receptacle. In another non-limiting embodiment, the electrical source can be secured to the circuit board using a snap fit, such as having a deformable lip on the mounting post that may deform around a rigid lip in the receptacle.

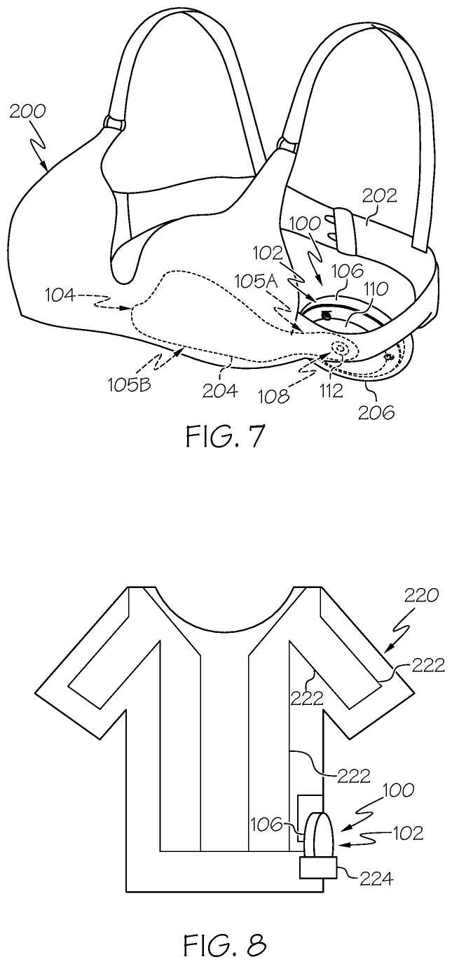

Referring now to FIG. 7, an embodiment of the heating device 100 is being used in combination with a garment, such as a bra 200. In some embodiments, the circuit board 104 is flexible so that the heating portion 105B may be arranged flush between a portion of the bra 200 and a human body wearing the bra 200. When the heating device 100 is being used with the bra 200, the electrical source 102 may be placed within a pouch 206. The pouch 206 is integral with the bra 200 on a strap 202 and positioned proximate to a target region 204 of the bra 200 so that heating portion 105B of the circuit board 104 is positioned over an associated target region of the human body. In some embodiments, the pouch 206 may be a half pouch or a full pouch that completely encases the electrical source 102. Additionally, in some embodiments, the circuit board 104 may be integral within the bra 200 with only the electrical source 102 being removed to clean the bra 200. The connector portion 105A allows the heating device 100 to be positioned away from the target region 204 for convenience and comfort for the user since the connector portion 105A electrically connects the heating portion 105B to the electrical source 102. In some embodiments, the pouch 206 may extend across the bra 200 such that the heating circuit 124 of the circuit board 104, or at least a portion thereof, may be provided within the pouch 206. In some embodiments, the heating device 100 can be used with the bra 200 without a pouch 206 and the heating device 100 may be held against the human body using the strap 202.

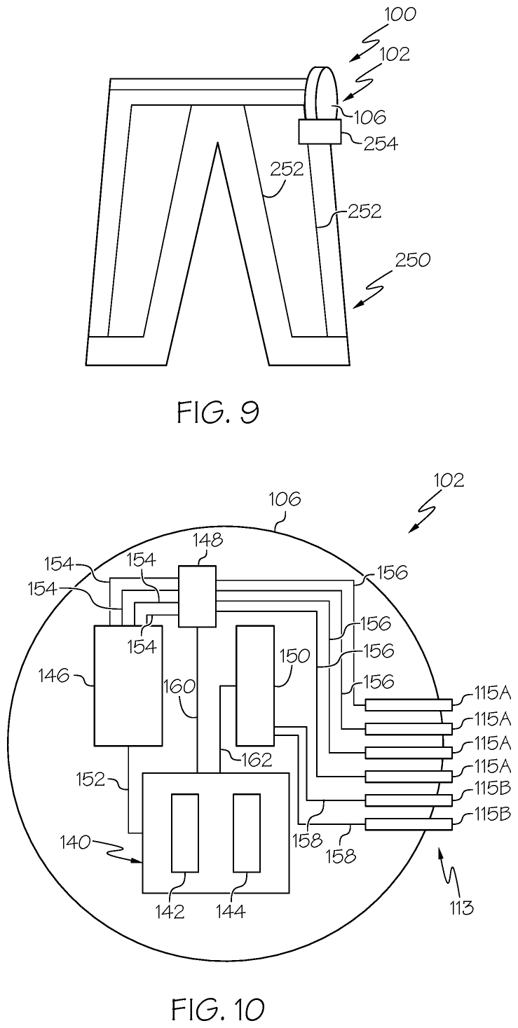

Referring now to FIGS. 8 and 9, the heating device 100 may be used with various other garments such as, for example, a shirt 220 and pants 250. In some embodiments, when the heating device 100 is in use with the shirt 220, the shirt 220 may include electrical conduits 222 embedded within the shirt 220. Electrical conduits 222 may be substantially similar to the heating circuit 124 within the circuit board 104. Additionally, the shirt 220 may further include a pouch 224 to house the electrical source 102 while a user is using the heating device 100 to heat the shirt 220. The pouch 224 may be a half pouch or a full pouch that completely encases the electrical source 102.

In some embodiments, when the heating device 100 is in use with pants 250, pants 250 may include electrical conduits 252 embedded within the pants 250. The electrical conduits 252 may be substantially similar to the heating circuit 124 within the circuit board 104. Additionally, the pants 250 may further include a pouch 254 to house the electrical source 102 while a user is using the heating device 100 to heat the pants 250. The pouch 254 may be a half pouch or a full pouch that completely encases the electrical source 102. Even though the heating device 100 is shown in use with a bra, shirt, and pants, it should be appreciated that any garment or flexible substrate could be used with the heating device 100.

Referring now to FIG. 10, a schematic view of an embodiment of the electrical source 102 is shown. The electrical source 102 may include a control unit 140 including a processor 142 and a computer readable memory 144, a battery 146, a switch 148, and a sensor 150. The control unit 140, the switch 148, and the sensor 150 are communicatively connected to the battery 146. The control unit 140 is communicatively connected to the battery 146 by a conduit 152. The switch 148 is communicatively connected to the battery 146 by conduits 154. The switch 148 is communicatively connected to the control unit 140 by a conduit 160. The sensor 150 is communicatively connected to the control unit 140 by a conduit 162.

Referring still to FIG. 10, the electrical source 102 may include electrical connectors 115A for providing electrical current to the circuit board 104 for heating purposes. The electrical connectors 115A are communicatively connected to the switch 148 by conduits 156. The switch 148 is controlled by the control unit 140, which can open or close the switch 148 to allow or prevent electricity from flowing from the battery 146 to the electrical connectors 115A.

Referring still to FIG. 10, in some embodiments, the electrical source 102 may include electrical connectors 115B for providing feedback information to the sensor 150 from the circuit board 104 via conduits 158, such as the temperature of a target region of the user or the heart rate of the user. The data received from electrical connectors 115B to the sensor 150 can then be transmitted to the control unit 140. The control unit 140 may then determine that the temperature of the target region of a user is higher than normal operating tolerances and may open the switch 148 to stop the flow of current to the circuit board 104 to let the target region cool down to normal operating tolerances. Additionally, if the control unit 140 determines that the temperature of the target region of a user is below normal operating temperature, the control unit 140 may close the switch 148 to begin the flow of current to the circuit board 104 to heat the target region to a temperature within the normal operating tolerances.

In some embodiments, the electrical source 102 may be powered by the battery 146. In some embodiments, the battery 146 may be two 3.7-volt lithium polymer (LiPo) batteries that may be connected in series, totaling to a usage voltage of 7.4 volts. The battery 146 may be removably or fixedly secured within the outer shell 106 of the electrical source 102. Additionally, the battery 146 can be either a rechargeable battery or a single-use battery. In some embodiments, the heating device 100 may not include the battery 146 and the heating device 100 may be powered through energy harvested from the environment, such as solar-powered.

In some embodiments, it can be contemplated that the features of the heating device 100 can be used in different application besides heating. The connection between the electrical source 102 and the circuit board 104, which utilizes the receptacle 116 and the mounting post 122, may be translated to other applications where a flexible circuit and a power source are required.

For example, the electrical source 102, the circuit board 104, and the connector assembly 108 could be used in combination with motion capture suits to detect the movement of people or objects in filmmaking, video games, entertainment, sports, medical applications, and military applications. Additionally, the embodiments disclosed herein can be used in applications including augmented reality/virtual reality where haptic feedback is provided to a user while wearing the circuit board 104. Another non-limiting example of an application may be for determining the spatial relationship between two objects.

Another non-limiting example of an application may be for the collection of physiological data using sensors and temperature control to record electrical activity produced by skeletal muscles of a patient. Sensors, such as those similar to electromyography (EMG), may be communicatively connected to the circuit board 104 and/or a controller via a connection similar to the connector assembly 108. EMG sensors can be utilized for monitoring physiological issues and neurological issues, while also helping with the study of kinesiology and the rehabilitation of known issues of a patient.

Another non-limiting example of an application may be for the delivery of therapy through electrical muscle stimulation (EMS), also known as neuromuscular electrical stimulation (NMES). Electrical signals could be sent to the skin of a patient via the circuit board 104 from the electrical source 102, which may be operatively arranged on the patient's skin to transfer the electrical signals to the patient's muscles.

Another non-limiting example of an application may be to collect basic patient statistics, such as heart rate and temperature, in an emergency situation. The circuit board 104 may be arranged on the patient's skin and connected to the electrical source 102 via the connector assembly 108. The circuit board 104 would be able to read a heart rate, temperature, or any other vital signs that may be reasonably determined from contact with a patient's skin. Additionally, the patient's vital signs may be transferred wirelessly via the electrical source 102 to another device, such as a computer, so first responders only need to carry the electrical source 102 and the circuit board 104.

Another non-limiting example of an application may be to provide heat to individuals in specific situations. For example, heating a user while using wetsuits, while also collecting data of the user. Additionally, using the circuit board 104 within the insole of a shoe for temperature control, data collection, and providing further data points, such as GPS, speed, impact force, heart rate, and blood pressure.

Another non-limiting example of an application may be applying the circuit board 104 to a surface to understand material science properties of the surface. For example, if the circuit board 104 is positioned around a tubular structure, the circuit board 104 may be used to register the torque force applied to the tubular structure. Examples of tubular structures may include a drive shaft, axel, bike frame, etc. Additionally, the circuit board 104 may be placed on or within skis, snowboards, or surfboards to determine the speed, torque, chatter, motion in aerial movement, relative position left versus right, and the centre of mass with a user. Additionally, the circuit board 104 may be arranged on or integrally within yoga mats or specialized work out mats to aid a user.

Another non-limiting example of an application may be for mapping of a patient's mouth or measuring a patient's bite strength. The circuit board 104 used could be shaped to fit with a human or animal mouth, while also being disposable. The circuit board 104 may contain impact sensors, which transmit data to the electrical source 102. The electrical source 102 may then transfer the data wirelessly to a computer for further processing of the data. The circuit board 104 may be used for creating dental devices, such as retainers or dental implants, or for determining if a patient grinds their teeth while sleeping.

It should now be understood that embodiments described herein are directed to a heating device for heating a target region. The heating device generally includes an electrical source and a circuit board. The electrical source includes an outer shell including a receptacle, a battery arranged within the outer shell, and at least one electrical connector electrically connected to the battery and extending through the outer shell. The circuit board includes at least one circuit element and a mounting post. When the mounting post of the circuit board is received within the receptacle of the outer shell, the at least one electrical connector of the electrical source is electrically coupled to the at least one circuit element of the circuit board. As described in greater detail herein, the electrical source may be easily and securely coupled to the circuit board. For example, the mounting post of the circuit board is held in place within the receptacle of the outer shell by a friction fit. Accordingly, this connection allows for easy removal of the circuit board from the electrical source for either replacement or cleaning of the circuit board.

It will be apparent to those skilled in the art that various modifications and variations can be made to the embodiments described herein without departing from the scope of the claimed subject matter. Thus, it is intended that the specification covers the modifications and variations of the various embodiments described herein provided such modifications and variations are within the scope of the appended claims and their equivalents.

1.-20. (canceled)

21. An apparatus comprising:
an electrical source comprising:
an outer shell;
a battery arranged within the outer shell; and
at least one electrical connector electrically connected to the battery; and
a circuit board comprising:
an inner layer;
an outer layer;
a heating portion comprising a heating circuit arranged between the outer layer and the inner layer of the circuit board; and
a connector portion between the outer layer and the inner layer of the circuit board extending from the heating portion, wherein a circuit element extends from between the inner layer and outer layer and is configured to electrically connect the heating circuit to the electrical connector.

22. The apparatus of claim 21, further comprising:
a plurality of mounting holes in either the outer shell or the connector portion; and
a plurality of mounting pins in the other of the outer shell or the connector portion,
wherein when the mounting pins are received in the mounting holes, the circuit element is electrically coupled to the electrical connector.

23. The apparatus of claim 21, further comprising:
a first plurality of mounting holes in either the outer shell or a support plate;
a second plurality of mounting holes in the connector portion; and
a plurality of mounting pins in the other of the outer shell or the support plate,
wherein when the mounting pins are received in the first plurality and second plurality of mounting holes, the connector portion is between the support plate and the outer shell, and the circuit element is electrically coupled to the electrical connector.

24. The apparatus of claim 23, wherein the support plate is rigid.

25. The apparatus of claim 21, wherein the connector portion extends a length from the heating portion and the circuit element runs generally parallel thereto a centerline of the length of the connector portion, wherein the outer layer in the connection portion does not extend outwardly from the centerline as much as the inner layer extends from the centerline of the connection portion.

26. The apparatus of claim 21, wherein the circuit board is flexible.

27. The apparatus of claim 21, wherein the heating circuit is flexible.

28. The apparatus of claim 21, wherein the heating circuit is made from an electrical conducting material, wherein the electrical conducting material is selected from electrical conducting ink and a positive temperature coefficient (PTC) heater.

29. The apparatus of claim 21, wherein the electrical source comprises a control unit, a battery, a switch, and a sensor.

30. The apparatus of claim 21, wherein the outer shell is rigid.

31. The apparatus of claim 30, wherein the outer shell is made from plastic.

32. The apparatus of claim 21, wherein the circuit element comprises exposed leads.

33. The apparatus of claim 21, further comprising a support layer, wherein the heating circuit is arranged on the support layer.

34. The apparatus of claim 33, wherein the support layer is flexible.

35. The apparatus of claim 33, further comprising a circuit layer on the support layer, wherein the heating circuit is arranged on the circuit layer prior to the circuit layer is secured to the support layer.

36. An apparatus comprising:
an electrical source comprising:
an outer shell;
a battery arranged within the outer shell; and
at least one electrical connector electrically connected to the battery and extending through the outer shell; and
a circuit board comprising:
an outer surface;
an inner surface;
a connector portion;
a heating portion comprising:
a heating circuit extending within the heating portion and to the connector portion; and
at least one circuit element,
a plurality of mounting holes in either the outer shell or the connector portion; and
a plurality of mounting pins in the other of the outer shell or the connector portion,
wherein when the mounting pins are received in the mounting holes, the circuit element is electrically coupled to the electrical connector.

37. The apparatus of claim 36, wherein the connector portion extends a length from the heating portion and the circuit element runs generally parallel thereto a centerline of the length of the connector portion, wherein an outer layer in the connection portion does not extend outwardly from the centerline as much as an inner layer in the connection portion extends from the centerline of the connection portion.

38. An apparatus comprising:
an electrical source comprising:
an outer shell;
a support plate connected to the outer shell;
a battery arranged within the outer shell; and
at least one electrical connector electrically connected to the battery and extending through the outer shell; and
a circuit board comprising at least one circuit element,
wherein the electrical connector of the electrical source is electrically coupled to the circuit element of the circuit board.

39. The apparatus of claim 38, further comprising:
a plurality of mounting holes in either the outer shell or a connector portion; and
a plurality of mounting pins in the other of the outer shell or the connector portion,
wherein when the mounting pins are received in the mounting holes, the circuit element is electrically coupled to the electrical connector.

40. The apparatus of claim 38, further comprising:
a first plurality of mounting holes in either the outer shell or a support plate;
a second plurality of mounting holes in the connector portion; and
a plurality of mounting pins in the other of the outer shell or the support plate,
wherein when the mounting pins are received in the first plurality and second plurality of mounting holes, the connector portion is between the support plate and the outer shell, and the circuit element is electrically coupled to the electrical connector.
